(19) United States
(12) Patent Application Publication
(10) Pub. No.: US 2008/0265932 A1
(43) Pub. Date: Oct. 30, 2008

(54) SEMICONDUCTOR TEST APPARATUS

(75) Inventor: HAJIME SHIBATA, TOKYO (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/926,119

(22) Filed: Oct. 28, 2007

Related U.S. Application Data
(63) Continuation of application No. PCT/JP2005/010264, filed on Jun. 3, 2005.

(51) Int. Cl. G01R 31/26

(52) U.S. Cl. 324/765

(57) ABSTRACT

A semiconductor test apparatus including a test apparatus body generating a test pattern supplied to a semiconductor device; a test head directly contacting the semiconductor device and supplying to the semiconductor device the generated test pattern; a cable passing the test pattern from the test apparatus body to the test head; a holding platform holding the test head in a movable manner; and a movable support section holding the cable, moving in a direction to release tension on a side closer to the test head than the test apparatus body in a case where tension arises in the cable because the test head moves on the holding platform, and moving in a direction to pull the cable on a side closer to the test head than the test apparatus body in a case where slack arises in the cable because the test head moves on the holding platform is provided.

### CROSS REFERENCE TO RELATED APPLICATION

This is a continuation application of PCT/JP2005/10264 filed on Jun. 3, 2005, the contents of which are incorporated herein by reference.

### BACKGROUND

1. Technical Field

The present invention relates to a semiconductor test apparatus and, more particularly, the present invention relates to a semiconductor test apparatus in which a test head is held on a holding platform in a movable manner.

2. Related Art

A semiconductor test apparatus supplies a test pattern to a semiconductor device under test, receives an output signal output by the semiconductor device based on the test pattern, and makes a judgment concerning pass/fail of the semiconductor device by comparing the received output signal to an expected value. A test apparatus body of the semiconductor test apparatus that generates the test pattern and the expected value receives the output signal of the semiconductor device under test and compares the received output signal to the expected value. The semiconductor device under test is placed on a test head, and the test apparatus body and the test head are connected via a connection cable.

The test head internally includes a performance board corresponding to a terminal array of the semiconductor device under test and a pin electronics substrate connecting the performance board to the connection cable. The semiconductor device under test is automatically supplied from a handler. In such a case, there is an upright handler that attaches and removes the semiconductor device from the performance board with the performance board standing vertically. To attach or remove, and thereby replace, the semiconductor device on the performance board using the upright handler, orientation of the test head is changed. Then, after the semiconductor device is replaced, the orientation of the test head is returned to the previous orientation and the semiconductor device is tested.

In a case where the orientation of the test head is changed, tension is placed on the connection cable connecting the test head to the test apparatus body by changing the orientation of the test head in relation to the test apparatus body, and therefore slackness occurs when the tension is released. In response to the aforementioned problem, a semiconductor test apparatus is provided with a movable support section that holds the cable and moves in a direction of a release of tension in a case where tension is placed on the cable (see, e.g., Patent Document 1).

### Patent Document 1: International Publication WO2005/026753

The movable support section described in the aforementioned Patent Document 1 moves downward in a case where tension is placed on the connection cable and moves upward when tension is released. Accordingly, in a case where the movable support section moves upward or downward, both sides of the connection cable supported by the movable support section are equally pulled in a longitudinal direction. In such a case, by pulling the connection cable, a pulling force is placed on the connected portion of the test apparatus body and the connection cable, resulting in a problem that the connected portion becomes separated. Furthermore, where the connection cable is lengthened to avoid placing the pulling force on the connected section, there is a problem that a delay or degradation of the test signal occurs.

### SUMMARY

Therefore, it is an object of an aspect of the present invention to provide a semiconductor test apparatus, which is capable of overcoming the above drawbacks accompanying the related art. The above and other objects can be achieved by combinations described in the independent claims. The dependent claims define further advantageous and exemplary combinations of the present invention.

According to a first aspect related to the innovations herein, one exemplary apparatus may include a semiconductor test apparatus. The semiconductor test apparatus includes a test apparatus body that generates a test pattern supplied to a semiconductor device; a test head that directly contacts the semiconductor device and supplies to the semiconductor device the test pattern generated by the test apparatus body; a cable that passes the test pattern from the test apparatus body to the test head; a holding platform that holds the test head in a movable manner; and a movable support section that holds the cable, moves in a direction to release tension on a side closer to the test head than the test apparatus body in a case where the tension arises in the cable because the test head moves in relation to the holding platform, and moves in a direction to be pull the cable on a side closer to the test head than the test apparatus body in a case where slack arises in the cable because the test head moves toward the holding platform.

According to a second aspect related to the innovations herein, one exemplary apparatus may include a semiconductor test apparatus. The semiconductor test apparatus includes a test apparatus body that executes testing by supplying an electric signal to a semiconductor device, a test head interposed between the semiconductor device and the test apparatus body, a cable that electrically connects the test apparatus body to the test head, a holding platform that holds the test head in a rotatable manner, and a movable support section that holds the cable. In the semiconductor test apparatus, the movable support section includes a rotating arm that, in a case where slack arises in the cable because the test head rotates in relation to the holding platform, rotates to hold the cable in a manner to curve the slack upward.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows a configuration of a semiconductor test apparatus 10 according to an embodiment of the present invention.

FIG. 2 shows a test head 100 in a rotated condition to exchange a pin electronics substrate.

FIG. 3 shows an exemplary detailed configuration of a movable support section 200.

FIG. 4 shows another example of a detailed configuration of the movable support section 200.

### DESCRIPTION OF EXEMPLARY EMBODIMENTS

Hereinafter, an embodiment of the present invention will be described. The embodiment does not limit the invention according to the claims, and all the combinations of the features described in the embodiment are not necessarily essential to means provided by aspects of the invention.

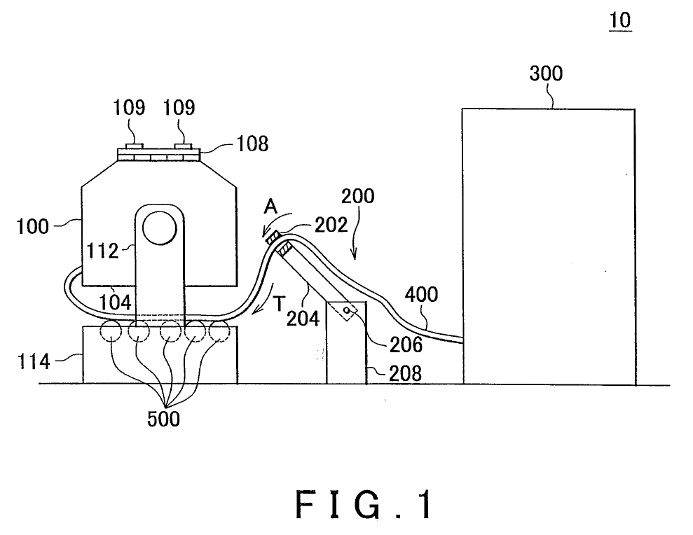

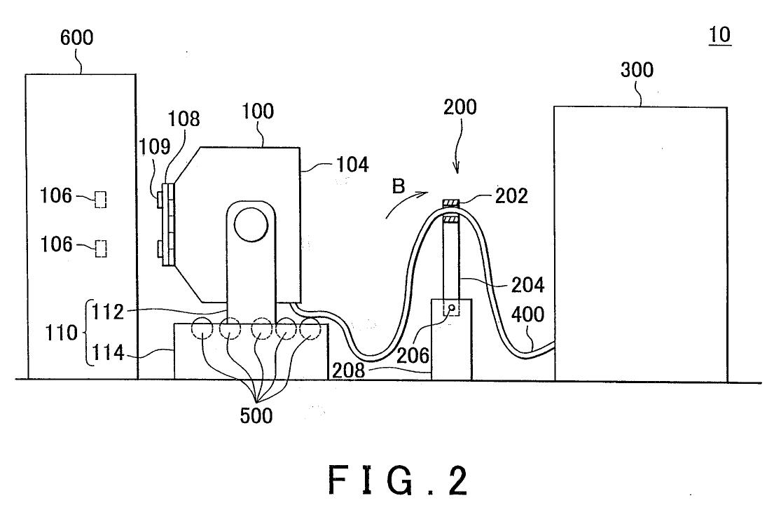

FIG. 1 shows a configuration of a semiconductor test apparatus 10 according to an embodiment of the present invention. FIG. 2 shows a test head 100 in a rotated condition. The semiconductor test apparatus 10 is provided with a test apparatus body 300, the test head 100, a movable support section 200, a connection cable 400, a plurality of rollers 500, and a handler 600. The semiconductor test apparatus 10 of the present invention aims to prevent disconnection and stress added to the connection cable 400 caused by rotation of the test head.

The test apparatus body 300 generates a test program supplied to a semiconductor device 106 under test. Furthermore, the test apparatus body 300 receives an output signal output by the semiconductor device 106 in response to the test pattern and makes a judgment concerning pass/fail of the semiconductor device 106 by comparing the received output signal to a predetermined value.

The connection cable 400 is connected to the test head 100 and the test apparatus body 300 and passes the test pattern from the test apparatus body 300 to the test head 100. Furthermore, the connection cable 400 passes the output signal output by the semiconductor device 106 in response to the test pattern from the test head 100 to the test apparatus body 300. The connection cable 400 is a bundle of several hundred wires including fat power source cables and signal cables. There is a case where, for example, a flat cable is included in which a plurality of transmission lines, such as optical fibers, are arranged in a flat manner. Furthermore, according to a system configuration, there is also a case where the connection cable 400 is a bundle containing several thousand of the aforementioned cables.

The test head 100 is provided with a plurality of pin electronics substrates and a device interface 108 connected to the pin electronics substrates. The device interface 108 is provided with a plurality of IC sockets 109 that electrically contact the semiconductor device 106. The device interface 108 is mechanically positioned to be joined to the handler 600. In such a joined condition, the semiconductor device 106 is transported inside the handler 600 and electrically connected to the IC sockets 109 to execute testing of the device. In a case where the type of semiconductor device 106 tested by the test head 100 is changed, the device interface 108 may be replaced accordingly. Furthermore, the device interface 108 can also be attached or removed in a case where a maintenance operation is executed. Because of this, the test head 100 is supported by a holding platform 110 that can move horizontally and, furthermore, the test head 100 is structured in a manner to rotate approximately ninety degrees.

In a case where the device interface 108 is replaced, the handler 600 shown in FIG. 2 is caused to stand vertically such that a surface connected to the test head 100 is on top. Therefore, the connection cable 400 is pulled approximately 1 m, adding a stress of tension T.

The holding platform 110 is provided with wheels, not shown, on a bottom of the platform base 114 to allow movement and holds the test head 100 in a movable manner. In the configuration shown in FIG. 1, the holding platform 110 includes a pair of holding arms 112 mounted on the platform base 114. The pair of holding arms 112 axially supports the test head 100 so that the test head 100 can be held by the holding platform 110 in a rotatable manner.

The plurality of rollers 500 causes the connection cable 400 to move smoothly without stress and is disposed in a rotatable manner on an upper surface of the platform base 114 of the holding platform 110. The rollers 500 support the connection cable 400 from below. In a case where the connection cable 400 is moved by slackening or increasing of tension on the connection cable 400, the rollers 500 supporting the connection cable 400 roll together along with the movement of the connection cable 400. Therefore, the rollers 500 can smoothly move the connection cable 400.

The movable support section 200 causes the connection cable 400 to move smoothly without stress and includes a platform base 208 joined with the platform base 114, a rotating arm 204 supported on the platform base 208 in a manner to be rotatable around a rotation axis 206, and a gripping section 202 disposed on an end portion of the rotating arm 204 that grips the connection cable 400. Wheels, not shown, are also disposed on a bottom portion to allow movement. The rotating arm 204 has an appropriate elasticity with respect to the rotational direction such that the rotating arm 204 stands upright, as shown in FIG. 2, in a condition where tension is not placed on the connection cable 400. In a condition where the connection cable 400 is held, the movable support section 200 moves between the position shown in FIG. 1 and the position shown in FIG. 2. The gripping section 202 may be a clip that sandwiches and holds the connection cable 400 or may be a clamp that sandwiches and holds the connection cable by the fastening force of a screw.

In a case where the test head 100 is in the condition shown in FIG. 1, the connected portion of the connection cable 400 connected to the test head 100 is in a position separated from the test apparatus body 300, so that the test head 100 pulls the connection cable 400. In such a case, the movable support section 200 moves in a direction to release the tension T on a side closer to the test head 100 than the test apparatus body 300. In the configuration shown in FIG. 1, in a case where the test head 100 pulls the connection cable 400, the gripping section 202 of the movable support section 200 is pulled to the left in the diagram by the tension T of the connection cable 400. Accordingly, the rotating arm 204 joined to the gripping section 202 rotates in a direction of an arrow A in the diagram around the rotation axis 206. Therefore, the gripping section 202 moves toward the test head 100, thereby releasing the tension placed on the connection cable 400 on a side of the test head 100. Here, it is desirable that the elasticity of the movable support section 200 in the axial direction be set to minimize the stress placed on the connection cable 400.

When the test head 100 rotates from the configuration shown in FIG. 1 to the configuration shown in FIG. 2, slack arises in the connection cable 400. When slack arises in the connection cable 400, there is a case where a portion of the connection cable 400 becomes heavy, causing buckling, and thereby creating a large amount of stress that, when repeated, results in disconnection. However, as shown in FIG. 2, in a case where the test head 100 moves towards the holding platform 110 together with the slackening of the connection cable 400, the movable support section 200 moves in a direction to pull the connection cable 400 on a side closer to the test head 100 than the test apparatus body 300. In such a case, because the pulling force placed on the connection cable 400 by the gripping section 202 is released by the slackening of the connection cable 400, the rotating arm 204 joined to the gripping section 202 rotates in a direction B in the diagram around the rotation axis 206. Accordingly, the gripping section 202 moves toward the test apparatus body 300, so that the slackened portion of the connection cable 400, which is the portion of the connection cable 400 on the side of the test head 100, is pulled by the movable support section 200. Therefore, buckling of the connection cable 400 can be prevented. Accordingly, disconnection of the connection cable 400 can be prevented. Furthermore, because the portion of the connection cable 400 on the side of the test head 100 is pulled, a burden placed on a connection point of the connection cable 400 and the test apparatus body 300 can be prevented. Yet further, deterioration of the connection cable 400 can be prevented.

On the other hand, where the test head 100 rotates from the condition shown in FIG. 2 to the condition shown in FIG. 1, an aperture 104 returns to a previous downward orientation. In such a case, the connection cable 400 is pulled by the test head 100 as the test head 100 rotates. Therefore, the tension T is placed on the connection cable 400. In a case where the tension T is placed on the connection cable 400 because the test head 100 moves in relation to the holding platform 110, the gripping section 202 of the movable support section 200 is pulled to the left in FIG. 1 by the tension T of the connection cable 400. Accordingly, the rotating arm 204 joined to the gripping section 202 rotates in a direction of the arrow A of FIG. 1 around the rotation axis 206. Therefore, the gripping section 202 moves toward the test head 100, thereby releasing the tension placed on the connection cable 400 on a side of the test head 100. Accordingly, disconnection of the connection cable 400 caused by an excessive tension can be prevented. Because the tension of the connection cable 400 on the side of the test head 100 is released, the burden placed on the connection point of the connection cable 400 and the test apparatus body 300 can be prevented.

In the embodiment shown in FIG. 1 and FIG. 2, the holding platform 110 holds the test head 100 in a rotatable manner, but is not limited to such. For example, in a case where the handler 600 can move horizontally, the holding platform 110 may be structured without wheels for moving. As another example, the holding platform 110 may hold the test head in a manner such that the test head 100 can be raised and lowered. In such a case, slack arising in the connection cable 400 can be prevented because the rotating arm 204 rotates toward the test apparatus body 300 at a time when the test head 100 is raised in relation to the test apparatus body 300, and furthermore, tension placed on the connection cable 400 can be released because the rotating arm 204 rotates toward the test head 100 at a time when the test head 100 is lowered in relation to the test apparatus body 300.

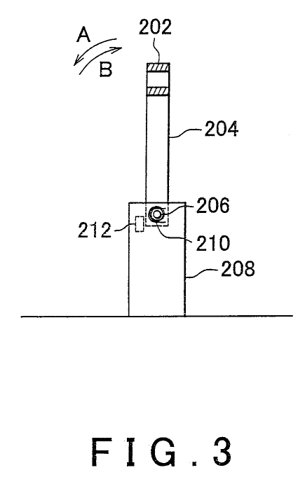

FIG. 3 shows an exemplary detailed configuration of the movable support section 200. The movable support section 200 includes the platform base 208, the rotation axis 206, the rotating arm 204, and the gripping section 202. Furthermore, the movable support section 202 includes a spring 210 disposed around the rotation axis 206 and a locking piece 202 projecting inside the platform base 208. The spring 210 causes the rotating arm 204 to be biased in a direction of the arrow B in the diagram. The locking piece 202 directly contacts a portion of the rotating arm 204 when the rotating arm 204 is in a position standing vertically and prohibits the rotating arm 204 from rotating further from the aforementioned position in a direction of the arrow B.

In the configuration shown in FIG. 3, in a case where the connection cable 400 gripped by the gripping section 202 is pulled by a tension T, the spring force of the spring 210 is set to be slightly less than the torque arising from the above case. Therefore, in a case where the test head 100 pulls the connection cable 400 with a tension T, the rotating arm 204 can rotate in a direction of the arrow A against the spring force of the spring 210. On the other hand, in a case where the connection cable 400 slackens, the rotating arm 204 is moved in a direction of the arrow B by the spring force of the spring 210 and stops at a position where the rotating arm 204 contacts the locking piece 204. As a result, the stress placed on the connection cable 400 is significantly reduced. Here, it is desirable that the spring be provided with an adjustment mechanism that adjusts the spring force of the spring 210 to minimize stress placed on the connection cable 400. Therefore, the appropriate spring force can be provided for different cable weights in the system configuration.

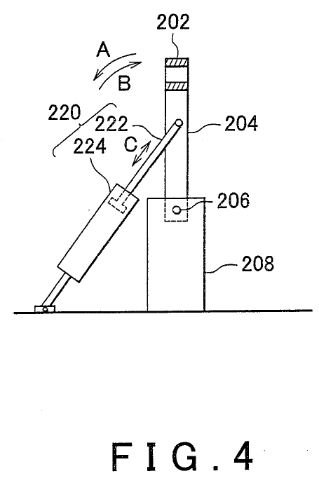

FIG. 4 shows another example of a detailed configuration of the movable support section 200. The movable support section 200 of FIG. 4 includes the platform base 208, the rotation axis 206, the 204, and the gripping section 202 in the same manner as the configuration of FIG. 3. Furthermore, the movable support section 400 of FIG. 4 includes an air cylinder apparatus 220 disposed between a floor or the like and the rotating arm 204. The air cylinder apparatus 220 includes a vacuum cylinder section 224 and a piston rod 222 that is inserted into the vacuum portion of the cylinder section 224 and slides in the cylinder section 224 in a direction of the arrow C in the diagram. In the air cylinder apparatus 220, the piston rod 222 is driven by pressure of gas injected into the cylinder section 224. In the present embodiment, the gas injected into the cylinder section 224 is dry air, for example.

The pressure of the gas in the cylinder section 224 is set to be, for example, less than the pressure supplied by the piston rod 222 to the gas in the cylinder section 224 according to a load placed on the gripping section 202 in a case where the connection cable 400 is most slackened and the piston rod 222 is raised to a highest point within a moveable range of the piston rod 222 and greater than the pressure supplied by the piston rod 222 to the gas in the cylinder section 224 according to a load placed on the gripping section 202 in a case where the connection cable 400 is least slackened and the piston rod 222 is lowered to a lowest point within the moveable range of the piston rod 222. It is desirable that the pressure of the gas in the cylinder section 224 be set such that an average value of the pressure supplied to the gas in the cylinder section 224 by the piston rod 222 in a case where the piston rod 222 is raised to the highest point be roughly equal to the pressure supplied to the gas in the cylinder section 224 by the piston rod 222 in a case where the piston rod 222 is lowered to the lowest point.

Through the configuration described above, in the same manner as the configuration shown in FIG. 3, the movable support section 200 of FIG. 4 can move the gripping section 202 in a direction of the arrow A in a case where the connection cable 400 is pulled by the test head 100 and can move the gripping section 202 in a direction of the arrow B in a case where the connection cable 400 is slackened. As a result, the stress placed on the connection cable 400 is significantly reduced.

As another example, a hydraulic driving apparatus that drives the piston rod by injected oil may be used in place of the air cylinder apparatus 220. As a further example, a spring or a gas spring that achieves an effect of a spring by using a repulsive force of gas sealed in the cylinder section may be used.

As made clear from the above description, through the semiconductor test apparatus 10 according to the present embodiment, a slackened portion of the connection cable 400 can be held without placing a burden on the section connected to the test apparatus body 300 in a case where slack arises in the connection cable 400 connecting the test head 100 to the test apparatus body 300, and furthermore, tension placed on the connection cable 400 can be released without placing a burden on the section connected to the test apparatus body 300 in a case where tension is placed on the connection cable 400.

While the embodiment of the present invention has been described, the technical scope of the invention is not limited to the above described embodiment. It is apparent to persons skilled in the art that various alterations and improvements can be added to the above-described embodiment. It is also apparent from the scope of the claims that the embodiments added with such alterations or improvements can be included in the technical scope of the invention.

As made clear from the above description, through an embodiment of the present invention, a semiconductor test apparatus is realized that can appropriately hold a connection cable without disconnection in a case where slack arises in the connection cable connecting a test apparatus body and a test head.

What is claimed is:

1. A semiconductor test apparatus, comprising:
a test apparatus body that generates a test pattern supplied to a semiconductor device;
a test head that directly contacts the semiconductor device and supplies to the semiconductor device the test pattern generated by the test apparatus body;
a cable that passes the test pattern from the test apparatus body to the test head;
a holding platform that holds the test head in a movable manner; and
a movable support section that holds the cable, moves in a direction to release tension on a side closer to the test head than the test apparatus body in a case where the tension arises in the cable because the test head moves in relation to the holding platform, and moves in a direction to be pull the cable on a side closer to the test head than the test apparatus body in a case where slack arises in the cable because the test head moves toward the holding platform.

2. The semiconductor test apparatus according to claim 1, wherein the holding platform holds the test head in a rotatable manner.

3. The semiconductor test apparatus according to claim 1, wherein the holding platform holds the test head in a manner such that the test head can be brought near to or separated from the test apparatus body.

4. The semiconductor test apparatus according to claim 1, wherein the holding platform holds the test head in a manner such that the test head can be raised or lowered.

5. The semiconductor test apparatus according to claim 1, wherein the movable support section includes a gripping section that grips the cable, rotates the gripping section toward the test apparatus in a case where tension arises in the cable, and rotates the gripping section toward the test head in a case where slack arises in the cable.

6. The semiconductor test apparatus according to claim 1, further comprising a roller that is arranged beneath the holding platform, supports the cable, and rotates along with movement of the cable.

7. A semiconductor test apparatus, comprising:
a test apparatus body that executes testing by supplying an electric signal to a semiconductor device;
a test head interposed between the semiconductor device and the test apparatus body;
a cable that electrically connects the test apparatus body to the test head;
a holding platform that holds the test head in a rotatable manner; and
a movable support section that holds the cable, wherein the movable support section includes a rotating arm that, in a case where slack arises in the cable because the test head rotates in relation to the holding platform, rotates to hold the cable in a manner to curve the slack upward.
